(19) United States
(12) Patent Application Publication
(10) Pub. No.: US 2014/0299476 A1
(43) Pub. Date: Oct. 9, 2014

(54) ELECTROPLATING METHOD

(71) Applicant: EBARA CORPORATION, Tokyo (JP)

(72) Inventors: Shingo YASUDA, Tokyo (JP); Akira OWATARI, Sacramento, CA (US); Mizuki NAGAI, Tokyo (JP); Akira SUSAKI, Tokyo (JP)

(21) Appl. No.: 14/228,188

(22) Filed: Mar. 27, 2014

Related U.S. Application Data
(60) Provisional application No. 61/810,049, filed on Apr. 9, 2013.

(51) Int. Cl. H01L 21/768

(52) U.S. Cl. CPC H01L 21/76877
USPC 205/131

(57) ABSTRACT

An electroplating method is disclosed. The method includes preparing a substrate having via holes in a surface thereof, performing a pretreatment of the substrate surface by immersing the substrate in a pretreatment liquid containing a plating suppressor to adsorb the plating suppressor onto the substrate surface, immersing the pretreated substrate in a plating solution containing a plating suppressor and a plating accelerator to replace the pretreatment liquid, attached to the substrate surface including interior surfaces of the via holes, with the plating solution, and then electroplating the substrate surface to fill the via holes with metal.

### CROSS REFERENCE TO RELATED APPLICATION

This document claims priority to U.S. Provisional Application No. 61/810,049 filed Apr. 9, 2013, the entire contents of which are hereby incorporated by reference.

### BACKGROUND

A technique of forming through-vias of a metal, such as copper, penetrating vertically through a semiconductor substrate is known as a method of electrically connecting layers of a multi-layer stack of semiconductor substrates.

FIGS. 1A through 1C show an exemplary process of producing a substrate having therein through-vias of copper. First, as shown in FIG. 1A, a substrate W is prepared by forming a plurality of upwardly-opening via holes 12 in a base 10, such as a silicon wafer, by using the lithography/etching technique or other technique, forming a dielectric film (not shown) on a surface of the base 10, including sidewalls of the via holes 12, forming a barrier layer 14 of a metal, such as Ti (titanium), on the entire surface of the base 10, including interior surfaces of the via holes 12, and then forming a copper seed layer 16 on a surface of the barrier layer 14 by PVD or other technique. A diameter “d” of the via holes 12 is, for example, 2 to 50 μm, in particular 10 to 20 μm, and a depth “h” of the via holes 12 is, for example, 20 to 150 μm.

Next, copper electroplating is carried out on the surface of the substrate W using the copper seed layer 16 as a cathode, thereby filling the via holes 12 with a plating metal (copper) 18 and depositing the plating metal 18 on the surface of the copper seed layer 16, as shown in FIG. 1B. In such a case where copper is embedded into the via holes 12 by copper electroplating, a copper sulfate plating solution, which is relatively inexpensive and is controlled relatively easy including its waste disposal, is widely used as a plating solution.

Thereafter, as shown in FIG. 1C, the excessive plating metal 18, copper seed layer 16, and barrier layer 14 on the base 10 are removed by chemical mechanical polishing (CMP) or the like. Further, a back side of the base 10 is polished away as shown by a two-dot chain line in FIG. 1C until a bottom face of the plating metal 18 embedded in the via holes 12 is exposed. The substrate W having therein the through-vias of copper (plating metal 18), vertically penetrating through the substrate W, can be produced in this manner.

The via holes 12 generally have a high aspect ratio, i.e., a depth-to-diameter ratio, and have a large depth. In order to completely fill copper (plating metal) into such via holes 12, having a high aspect ratio and a large depth, by electroplating without producing defects, such as voids, in the embedded metal, it is usually necessary to perform the electroplating in a bottom-up manner of allowing the plating metal to grow preferentially from the bottoms of the via holes 12.

Such bottom-up plating is generally carried out by using a copper sulfate plating solution containing various additives which includes a plating accelerator that accelerates the deposition of the plating metal in the via-holes, such as SPS (bis (3-sulfopropyl)disulfide), a plating suppressor that suppresses the deposition of the plating metal on a surface of a field area of the substrate, such as PEG (polyethylene glycol), and a leveler, such as PEI (polyethylene imine). These additives exert their effects after they are adsorbed onto a surface of a substrate.

The applicant has proposed a plating method which makes it possible to fill a void-free plating metal into recesses formed in a substrate surface at a higher plating rate. This plating method includes the steps of carrying out a first pretreatment by immersing a substrate in a first pretreatment liquid containing a plating accelerator, a metal ion and an acid, carrying out a second pretreatment by immersing the substrate in a second pretreatment liquid containing an additive which inhibits the effect of the plating accelerator and not containing a plating accelerator, and subsequently carrying out electroplating of the substrate (see Japanese Laid-Open Patent Publication No. 2011-174177).

A method has also been proposed which uses, as a pre-electroplating treatment solution, an aqueous solution containing essential components, which are: (A) at least one anti-adhesion agent selected from a triazole compound, a pyrazole compound, an imidazole compound, a cationic surfactant, and an amphoteric surfactant; and (B) a chloride ion (see Japanese Laid-Open Patent Publication No. 2011-179085).

The plating accelerator and the plating suppressor are additives essential to a so-called “bottom-up” plating method which involves preferentially depositing a plating metal on the bottoms of the via holes of the substrate while suppressing the deposition of the plating metal on the surface of the field area of the substrate.

However, when plating of the substrate to fill a plating metal into the via holes, having a relatively high aspect ratio, is carried out using, for example, a plating solution containing a plating suppressor comprising PEG in an amount of about 7.5 ml/L, deposition of the plating metal will be promoted around the openings of the via holes. The openings of the via holes will therefore be closed by the plating metal before bottom-up filling of the plating metal into the via holes is completed, resulting in formation of voids in the plating metal embedded in the via holes.

In the case of carrying out plating of a substrate so as to fill a plating metal into via holes having a relatively large aspect ratio using, for example, a plating solution containing a plating suppressor comprising PEG in an amount as high as about 15 ml/L in order to prevent the formation of voids in the plating metal embedded in the via holes, the use of such a plating solution has the following problem. As can be seen in FIGS. 2 and 3, a rapid decrease in a plating rate will occur as a height H1 of a plating metal 18 embedded in via holes 12 reaches e.g., about 60 to 90% (this value may vary depending on the aspect ratio of the via holes 12) of an overall height H2 of the via holes 12 (H1/H2≈0.6-0.9).

This is considered to be due to the following reason. As the recesses (the via holes) in the substrate surface become shallower with the progress of filling of the plating metal into the via holes, the plating suppressor contained in the plating solution comes to act on the surface of the metal surface, embedded in the via holes, in the same way as on the surface of the field area of the substrate. If the plating solution is one containing the plating suppressor in a high concentration, such as a plating solution containing a PEG suppressor in an amount of about 15 ml/L, a considerably large amount of the plating suppressor will be adsorbed onto the surface of the plating metal embedded in the via holes, thus leading to a remarkable decrease in the plating rate.

A strong demand therefore exists for a plating method which uses a plating solution containing a plating suppressor, such as PEG, in a relatively low concentration, e.g., about 7.5 ml/L of PEG in order to prevent a rapid decrease in the plating rate before filling of the plating metal into the via holes is completed, while avoiding the formation of the voids in the plating metal embedded in the via holes despite the use of such a plating solution.

### SUMMARY OF THE INVENTION

It is therefore an object to provide an electroplating method which can prevent a rapid decrease in a plating rate during via-hole filing plating by using a plating solution containing a plating suppressor in a relatively low concentration, and can fill a void-free plating metal into via holes despite the use of such a plating solution having a low concentration of the plating suppressor.

An embodiment provides an electroplating method which is useful for filling via holes with a metal, such as copper, in manufacturing of a substrate, such as a semiconductor substrate or the like, which has a number of through-vias (via plug) vertically penetrating in its interior, and which can be used in so-called three-dimensional packaging of semiconductor chips.

An embodiment provides an electroplating method comprising: preparing a substrate having via holes in a surface thereof; performing a pretreatment of the substrate surface by immersing the substrate in a pretreatment liquid containing a plating suppressor to adsorb the plating suppressor onto the substrate surface; immersing the pretreated substrate in a plating solution containing a plating suppressor and a plating accelerator to replace the pretreatment liquid, attached to the substrate surface including interior surfaces of the via holes, with the plating solution; and then electroplating the substrate surface to fill the via holes with metal.

According to this method, the plating suppressor is adsorbed onto the substrate surface by the pretreatment performed in advance of plating of the substrate. As a result, even if plating of the substrate is carried out using a plating solution containing a plating suppressor, such as PEG, in a relatively low concentration about, e.g., 7.5 ml/L, the plating suppressor that has been adsorbed on the substrate surface, together with the plating suppressor contained in the plating solution, can prevent the formation of voids in the plating metal embedded in the via holes. Moreover, the use of such plating solution containing the plating suppressor in a relatively low concentration can reduce an amount of the plating suppressor adsorbed on the surface of the plating metal embedded in the via holes, thereby preventing a rapid decrease in the plating rate during filling of the via holes with the plating metal.

In an embodiment, a ratio of a concentration of the plating suppressor in the pretreatment liquid to a concentration of the plating suppressor in the plating solution is in a range of 20 to 200%.

In an embodiment, the ratio is in a range of 20 to 30%.

In an embodiment, the plating suppressor comprises polyethylene glycol.

In an embodiment, the pretreatment liquid further contains a metal ion and a halide ion. A pH of the pretreatment liquid may be in a range of 4 to 6.

In an embodiment, a concentration of oxygen dissolved in the pretreatment liquid is not more than 2 mg/L. The pretreatment liquid having such a low concentration of the dissolved oxygen (i.e., 2 mg/L or less) can securely enter the via holes of the substrate in the pretreatment of the substrate.

In an embodiment, immersing the pretreated substrate in the plating solution comprises immersing the pretreated substrate in a plating solution containing a plating suppressor and a plating accelerator to replace the pretreatment liquid, attached to the substrate surface including interior surfaces of the via holes, with the plating solution while agitating the plating solution. Agitating the plating solution can promote the replacement of the pretreatment liquid, existing in the via holes of the substrate, with the plating solution.

In an embodiment, the electroplating method further comprises, before immersing the pretreated substrate in the plating solution, cleaning the pretreated substrate with water. By cleaning the substrate with the water after the pretreatment, the excessive pretreatment liquid adhering to the substrate surface can be removed in advance.

An embodiment provides an electroplating method comprising: preparing a substrate having via holes in a surface thereof; performing electrolytic processing of the substrate surface by applying a voltage between an anode and the substrate immersed in a plating solution to deposit metal on the substrate, thereby embedding the metal in the via holes; performing reverse electrolytic processing of the substrate surface by passing an electric current between the anode and the substrate in a direction opposite to a direction of the electric current in the electrolytic processing, the reverse electrolytic processing being started when a height of the metal embedded in the via holes reaches about 60 to 90% of an overall height of the via holes; and then performing the electrolytic processing again to further embed the metal in the via holes.

According to this method, when the height of the metal embedded in the via holes reaches about 60 to 90%, preferably about 60 to 70% or about 70 to 90% of the overall height of the via holes, the reverse electrolytic processing is performed by passing the electric current between the anode and the substrate in the opposite direction, i.e., in a direction opposite to a direction of the electric current when plating of the substrate is performed. This reverse electrolytic processing can etch away the surface of the plating metal embedded in the via holes on which a large amount of the plating suppressor has been adsorbed, and can therefore prevent a rapid decrease in the plating rate.

In an embodiment, the electroplating method further comprises, after performing the reverse electrolytic processing and before performing the electrolytic processing again, performing zero-current processing of the substrate surface without passing the electric current between the anode and the substrate. By carrying out the zero-current processing, the plating suppressor can be re-adsorbed onto the surface of the plating metal which has been etched and exposed by the reverse electrolytic processing.

In an embodiment, the plating solution contains a plating suppressor. The use of the plating solution containing the plating suppressor in an amount of, e.g., about 15 ml/L can prevent the formation of voids in the plating metal embedded in the via holes.

In an embodiment, the electrolytic processing is performed while agitating the plating solution.

According to the above-described embodiment of the electroplating method, the plating suppressor is adsorbed in advance onto the substrate surface by the pretreatment that is performed in advance of plating of the substrate. This can prevent the formation of voids in the metal embedded in the via holes even if plating of the substrate is carried out with use of a plating solution containing a plating suppressor in a relatively low concentration. Moreover, the use of such a plating solution containing the plating suppressor in a relatively low concentration leads to a decrease in the amount of the plating suppressor adsorbed on the surface of the metal embedded in the via holes, and can therefore prevent a rapid decrease in the plating rate during the via-hole filing plating.

According to the above-described embodiment of the electroplating method, the reverse electrolytic processing is carried out when the height of the metal embedded in the via holes reaches about 60 to 90% of the overall height of the via holes, thereby etching away the surface of the metal embedded in the via holes. This can prevent a rapid decrease in the plating rate even if plating of the substrate is carried out using a plating solution containing a plating suppressor in a relatively high concentration in order to fill the via holes with a void-free metal.

### BRIEF DESCRIPTION OF THE DRAWINGS

FIGS. 1A through 1C are diagrams illustrating a sequence of process steps of producing a substrate having a plurality of copper through-vias vertically penetrating through the substrate;

FIG. 2 is a diagram illustrating a relationship between a height of a plating metal embedded in a via hole and an overall height of the via hole;

FIG. 3 is a graph showing a relationship between time and a via-hole filling ratio in a via-hole filing plating process as carried out by using a plating solution containing PEG as a plating suppressor in a concentration of about 15 ml/L;

FIG. 4 is an overall layout plan view of a plating facility for carrying out the electroplating method according to an embodiment;

FIG. 5 is a schematic view of a transport robot provided in the plating facility shown in FIG. 4;

FIG. 6 is a schematic cross-sectional view of a plating apparatus provided in the plating facility shown in FIG. 4;

FIG. 7 is a plan view of an agitating paddle (agitating tool) provided in the plating apparatus shown in FIG. 6;

FIG. 8 is a cross-sectional view taken along line A-A of FIG. 7;

FIG. 9 is a flow chart illustrating the electroplating method according to an embodiment;

FIG. 10 is a graph showing a relationship between a plating rate and a height of a plating metal embedded in via holes in a via-hole filing plating process as performed by the electroplating method according to the embodiment;

FIG. 11 is a diagram showing experimental results showing a relationship between a concentration of a plating suppressor (an additive) comprising PEG in a pretreatment liquid and in a plating solution and formation of voids in a plating metal embedded in the via holes;

FIG. 12 is a graph showing a relationship between time and a value of electric current flowing between an anode and a substrate surface, as observed when a voltage is applied between the anode and the substrate surface during plating performed by the plating method according to the embodiment; and

FIG. 13 is a graph showing a relationship between time and a via-hole filing ratio in the via-hole filing plating process as performed by the electroplating method according to the embodiment.

### DETAILED DESCRIPTION OF EMBODIMENTS

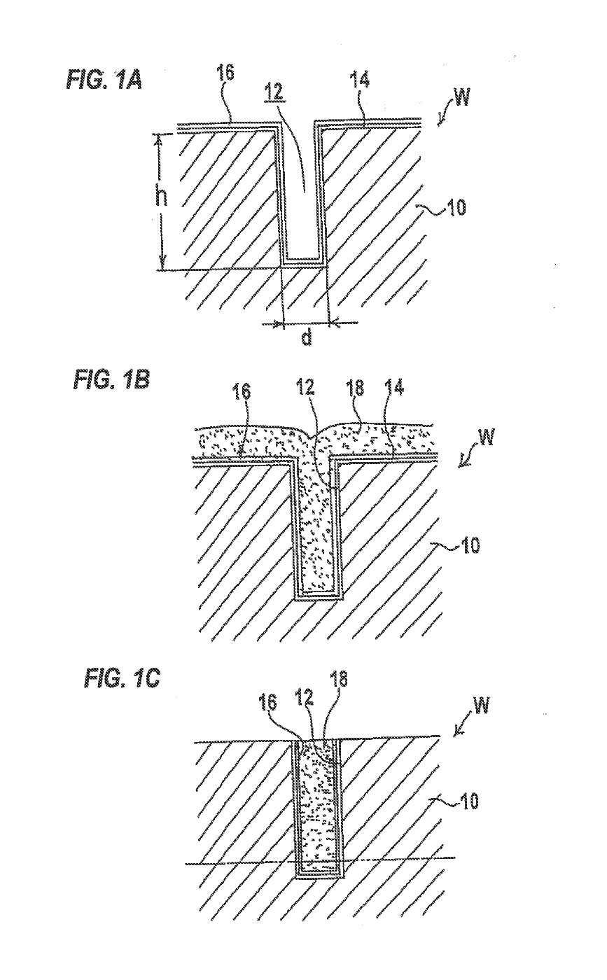

Embodiments will now be described with reference to the drawings. The following description illustrates an exemplary case in which a substrate W with a barrier layer 14 and a copper seed layer 16 formed successively on an entire surface of the substrate W, including surfaces of via holes 12, as shown in FIGS. 1A through 1C, is prepared. Then, a copper electroplating process is carried out on the surface of the substrate W using a copper sulfate plating solution, thus filling the via holes 12 with copper, i.e., a plating metal, to thereby form through-vias of copper in the substrate W.

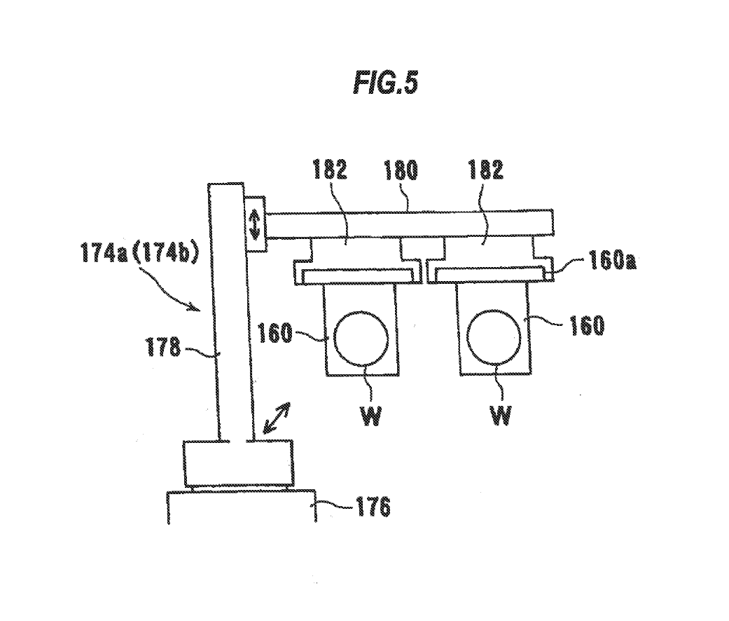

FIG. 4 is an overall layout plan view of a plating facility used for carrying out an electroplating method of the embodiment. This plating facility is designed so as to automatically perform all plating processes including a pretreatment of a substrate, plating of the substrate, and a post-treatment of the plated substrate, in a successive manner. An interior of an apparatus frame 110 having an armored panel attached thereto is divided by a partition plate 112 into a plating space 116 for performing a plating process of a substrate and treatments of the substrate to which a plating solution is attached, and a clean space 114 for performing other processes, i.e., processes not directly involving a plating solution. Two substrate holders 160 (see FIG. 5) are arranged in parallel. Substrate loading and unloading stages 162 to attach a substrate to and remove the substrate from each substrate holder 160 are provided as a substrate transfer section on a partition portion partitioned by the partition plate 112, which separates the plating space 116 from the clean space 114. Loading and unloading ports 120, on which substrate cassettes each storing substrates therein are mounted, are connected to the clean space 114. Further, the apparatus frame 110 has a console panel 121 provided thereon.

In the clean space 114, there are disposed an aligner 122 for aligning an orientation flat or a notch of a substrate with a predetermined direction, two cleaning and drying devices 124 for cleaning a plated substrate and rotating the plated substrate at a high speed to spin-dry the plated substrate. Further, a first transfer robot 128 is disposed substantially at the center of these devices, i.e., the aligner 122 and the cleaning and drying devices 124, so as to transfer and deliver a substrate between the devices 122, 124, the substrate loading and unloading stages 162, and the substrate cassettes mounted to the loading and unloading ports 120.

The aligner 122 and the cleaning and drying devices 124 disposed in the clean space 114 are designed so as to hold and process a substrate in a horizontal position with a front face of the substrate facing upward. The first transfer robot 128 is designed so as to transfer and deliver a substrate in a horizontal position with a front face of the substrate facing upward.

In the plating space 116, in the order from the partition plate 112, there are disposed a storage unit 164 for storing or temporarily placing substrate holders 160 therein, a pretreatment device 166 for carrying out a pretreatment (or a pre-wetting treatment) for improving a hydrophilicity of the surface of the substrate by immersing the substrate into a pretreatment liquid, a first water-cleaning device 168a for cleaning the surface of the substrate with pure water, an electroplating device 170 for carrying out electroplating of the substrate, a second water-cleaning device 168b, and a blowing device 172 for dewatering the plated substrate. Two second transfer robots 174a, 174b, which are movable along a rail 176, are disposed beside these devices. The second transfer robots 174a is configured to transfer the substrate holders 160 between the substrate loading and unloading stages 162 and the storage unit 164. The other second transfer robots 174b is configured to transfer the substrate holders 160 between the storage unit 164, the pretreatment device 166, the first water-cleaning device 168a, the electroplating device 170, the second water-cleaning device 168b, and the blowing device 172.

As shown in FIG. 5, each of the second transfer robots 174a, 174b has a body 178 extending in a vertical direction and an arm 180 which is vertically movable along the body 178 and rotatable about its axis. The arm 180 has two substrate holder retainers 182 provided in parallel for detachably holding or retaining the substrate holders 160. Each substrate holder 160 is designed so as to detachably hold a substrate W in a state such that a front face of the substrate is exposed while a peripheral portion of the substrate is sealed.

The storage unit 164, the pretreatment device 166, the water-cleaning devices 168a, 168b, and the electroplating device 170 are designed so as to engage with outwardly projecting portions 160a provided at both ends of each substrate holder 160 to thus support the substrate holders 160 in a state such that the substrate holders 160 are suspended in a vertical position.

The pretreatment device 166 has two pretreatment baths 183 each for holding therein the pretreatment liquid containing a plating suppressor and a deaerated water, such as pure water (deaerated DIW), having a dissolved oxygen concentration of, e.g., not more than 2 mg/L. The plating suppressor contained in this pretreatment liquid is of the same type as a plating suppressor that is contained in a plating solution, which will be discussed later. In this embodiment, the plating suppressor containing PEG (polyethylene glycol) is added to the deaerated water. As shown in FIG. 5, the arm 180 of the second transfer robot 174b holding the substrate holders 160, which are loaded with the substrates W in a vertical position, is lowered until the substrate holders 160 are supported in a suspended manner by upper ends of the pretreatment baths 183. Thus, the first pretreatment device 166 is designed so that the substrate holders 160 are immersed together with the substrates W in the pretreatment liquid held in the pretreatment baths 183 to thereby carry out the pretreatment (i.e., the pre-wetting treatment) of the surface of the substrate.

In this manner, the pretreatment is performed by immersing each substrate W in the pretreatment liquid containing PEG as the plating suppressor, so that PEG (the plating suppressor) is adsorbed on the surface of the substrate W in advance. A concentration of the plating suppressor (e.g., PEG) contained in the pretreatment liquid is about 2.0 ml/L. The substrate W is immersed in this pretreatment liquid for, e.g., 1 to 10 minutes. Since the pure water having a dissolved oxygen concentration of not more than 2 mg/L is used in the pretreatment liquid, the pretreatment liquid can reliably enter the via holes 12 when the substrate is immersed in the pretreatment liquid.

The pretreatment liquid may further contain metal ions (or copper ions) and halide ions, preferably chloride ions. The pretreatment liquid is adjusted to have a pH in a range of 4 to 6. A buffering agent for pH adjustment, such as phosphate, phthalate, citrate, succinate or boracic acid, may be added to the pretreatment liquid in order to suppress pH fluctuation of the pretreatment liquid.

Similarly, the water-cleaning devices 168a, 168b have two water-cleaning baths 184a and two water-cleaning baths 184b, respectively, which hold pure water therein, and the electroplating device 170 has a plurality of plating baths 186 each holding a plating solution therein. The water-cleaning devices 168a, 168b are designed so that the substrate holders 160 are immersed together with the substrates W in the pure water in the water-cleaning baths 184a, 184b to carry out water-cleaning of the substrates W in the same manner as described above. The electroplating device 170 are designed so that the substrate holders 160 are immersed together with the substrates W in the plating solution in the plating baths 186 to carry out plating of the substrates W.

The arm 180 of the second transfer robot 174b holding the substrate holders 160, which are loaded with substrates W in a vertical position, is lowered until the substrates W, held by the substrate holders 160, are placed in the blowing device 172. Air or inert gas is then ejected toward the substrates W mounted on the substrate holders 160 to blow away a liquid attached to the substrate holders 160 and the substrates W to thereby drain the liquid off the substrates W. In this manner, the blowing device 172 is designed so as to carry out a blowing treatment.

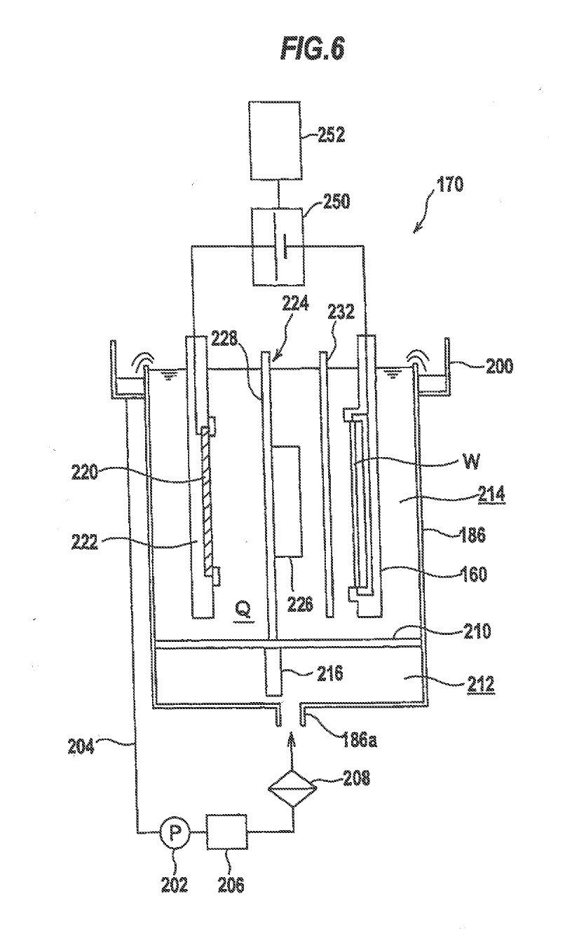

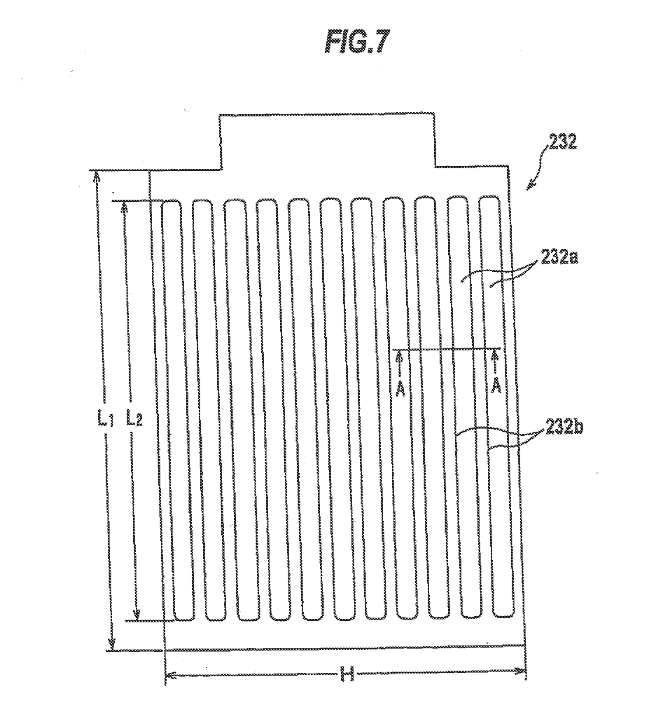

As shown in FIG. 6, each plating bath 186 of the electroplating device 170 is designed to hold a predetermined amount of plating solution Q therein. The substrates W, which are held in a state such that the front faces (surfaces to be plated) are exposed while peripheral portions of the substrates are watertightly sealed by the substrate holders 160, are immersed in the plating solution Q in a vertical position.

In this embodiment, an acidic copper sulfate plating solution is used as the plating solution Q. This acidic copper sulfate plating solution contains sulfuric acid, copper sulfate, halide ions, and various additives, such as SPS (bis (3-sulfopropyl)disulfide) serving as a plating accelerator, PEG (polyethylene glycol) serving as a suppressor, and PEI (polyethylene imine) serving as a leveler. A concentration (or an amount added) of the plating suppressor comprising PEG in the plating solution Q is about 7.5 ml/L. Chlorine ions are preferably used as the halide ions.

The plating suppressor may be, other than PEG, polypropylene glycol, a copolymer of ethylene glycol and propylene glycol, a derivative polyvinyl alcohol of these substances, or carboxymethyl cellulose.

An overflow bath 200 for receiving the plating solution Q that has overflowed an edge of the plating bath 186 is provided around an upper end of the plating bath 186. One end of a circulation pipe 204, which is provided with a pump 202, is coupled to a bottom of the overflow bath 200, and the other end of the circulation pipe 204 is coupled to a plating solution supply inlet 186a provided at a bottom of the plating bath 186. Thus, the plating solution Q in the overflow bath 200 is returned into the plating bath 186 by the operation of the pump 202. Located downstream of the pump 202, a constant-temperature unit 206 for regulating a temperature of the plating solution Q and a filter 208 for filtering out (or removing) foreign matter from the plating solution are mounted to the circulation pipe 204.

A bottom plate 210, having a large number of plating solution passage holes therein, is installed in the bottom of the plating bath 186. The interior of the plating bath 186 is thus separated by the bottom plate 210 into an upper substrate processing chamber 214 and a lower plating solution dispersion chamber 212. Further, a shield plate 216, extending vertically downward, is mounted to the lower surface of the bottom plate 210.

According to this electroplating device 170, the plating solution Q is introduced into the plating solution dispersion chamber 212 of the plating bath 186 by the operation of the pump 202, flows into the substrate processing chamber 214 through the plating solution passage holes provided in the bottom plate 210, flows vertically approximately parallel to the surface of the substrate W held by the substrate holder 160, and then flows into the overflow bath 200.

An anode 220 having a circular shape corresponding to the shape of the substrate W is held by an anode holder 222 and provided vertically in the plating bath 186. When the plating bath 186 is filled with the plating solution Q, the anode 220 held by the anode holder 222 becomes immersed in the plating solution Q in the plating bath 186 and faces the substrate W held by the substrate holder 160 that is placed in the plating bath 186.

Further, in the plating bath 186, a regulation plate 224 for regulating distribution of electric potential in the plating bath 186 is disposed between the anode 220 and the substrate holder 160 disposed at a predetermined position in the plating bath 186. In this embodiment, the regulation plate 224 is constituted by a cylindrical portion 226 and a rectangular flange portion 228, and is made of polyvinyl chloride that is a dielectric material. The cylindrical portion 226 has such an opening size and axial length as to sufficiently restrict broadening of an electric field. A lower end of the flange portion 228 of the regulation plate 224 reaches the bottom plate 210.

Between the regulating plate 224 and the substrate holder 160 disposed in the plating bath 186 is disposed a vertically-extending agitating paddle 232 as an agitating tool which reciprocates parallel to the surface of the substrate W to agitate the plating solution Q between the substrate holder 160 and the regulating plate 224. By agitating the plating solution Q with the agitating paddle (agitating tool) 232 during plating, a sufficient amount of copper ions can be supplied uniformly to the surface of the substrate W.

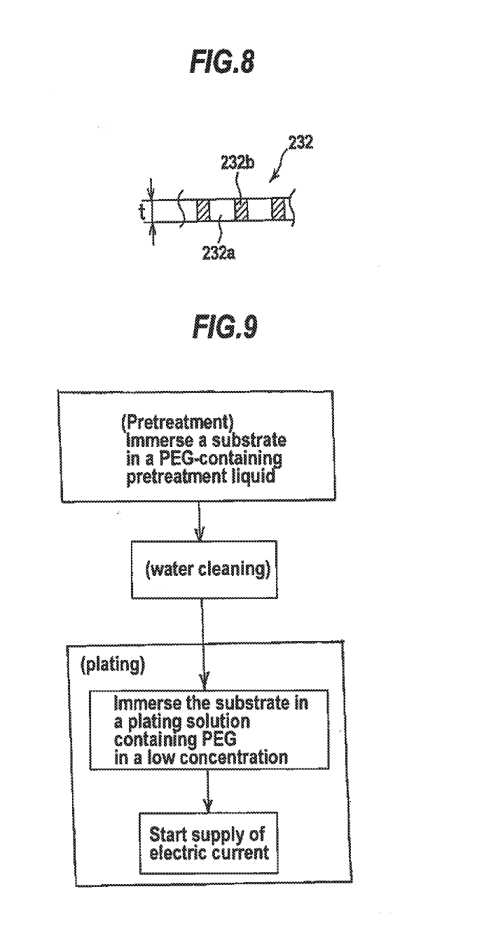

As shown in FIGS. 7 and 8, the agitating paddle 232 is constituted by a rectangular plate-like member having a uniform thickness “t” in a range of 3 to 5 mm, and has a plurality of parallel slits 232a that define vertically-extending strip-like portions 232b. The agitating paddle 232 is formed of, for example, a resin such as PVC, PP, or PTFE, or SUS or titanium with a fluororesin coating. It is preferred that at least part of the agitating paddle 232, which contacts the plating solution, be electrically isolated. A vertical length L₁ of the agitating paddle 232 and a vertical length L₂ of the slits 232a are sufficiently larger than the vertical size of the substrate W. Further, the agitating paddle 232 is so designed that the sum of its lateral length H and its reciprocation distance (stroke) is sufficiently larger than the lateral size of the substrate W.

It is preferred that a width and the number of slits 232a be determined such that each strip-shaped portion 232b is as narrow as possible insofar as it has the necessary rigidity so that the strip-shaped portions 232b between the slits 232a can efficiently agitate the plating solution and, in addition, the plating solution can efficiently pass through the slits 232a.

The electroplating device 170 is provided with a plating power source 250 having a positive pole connected via a conducting wire to the anode 220 and a negative pole connected via a conducting wire to the surface of the substrate W during plating. The plating power source 250 is coupled to a controller 252, and the plating power source 250 is controlled based on signals from the controller 252.

A series of plating processes, to be carried out by the plating facility shown in FIG. 4, for electroplating the surface of the substrate W with the barrier layer 14 and the copper seed layer 16 formed successively on the entire surface thereof including the surfaces of the via holes 12 as shown in FIGS. 1A through 1C, using the copper sulfate plating solution, so as to fill the via holes 12 with a plating metal, i.e., copper, will be described below with reference to FIG. 9.

First, the substrate W is placed, with its front surface (surface to be plated) facing upwardly, in the substrate cassette, and the substrate cassette is mounted to the loading and unloading port 120. One of the substrates W is taken out of the substrate cassette by the first transfer robot 128 and placed on the aligner 122, which aligns an orientation flat or a notch of the substrate W with a predetermined direction. Two substrate holders 160, which have been stored in a vertical position in the storage unit 164, are taken out by the second transfer robot 174a, rotated through 90° so that the substrate holders 160 are brought into a horizontal position, and then placed in parallel on the substrate loading and unloading stages 162.

The substrates W aligned the orientation flat or the notch thereof with a predetermined direction are transported and loaded into the substrate holders 160 placed on the substrate loading and unloading stages 162 in a state such that the peripheral portions of the substrates are sealed. The two substrate holders 160, which have been loaded with the substrates W, are simultaneously gripped, lifted, and then transported to the storage unit 164 by the second transfer robot 174a. The substrate holders 160 are rotated through 90° into a vertical position and lowered so that the two substrate holders 160 are held (temporarily stored) in the storage unit 164 in a suspended manner. These operations are carried out repeatedly in a sequential manner, so that substrates are sequentially loaded into the substrate holders 160, which have been stored in the storage unit 164, and the substrate holders 160, loaded with the substrates W, are sequentially held (temporarily placed) in the storage unit 164 at predetermined positions in a suspended manner.

The two substrate holders 160, which have been loaded with the substrates and temporarily placed in the storage unit 164, are simultaneously gripped, lifted, and then transported to the pretreatment device 166 by the second transfer robot 174b. In the pretreatment device 166, the substrates W held by the substrate holders 160 are immersed in the pretreatment liquid held in the pretreatment baths 183, so that the pretreatment (or the pre-wetting treatment) is carried out on the surfaces of the substrates W.

The pretreatment liquid used in this embodiment is constituted by the pure water containing the plating suppressor comprising PEG, which is the same as a plating suppressor contained in the plating solution Q, with a concentration of about 2.0 ml/L. The substrate W is immersed in this pretreatment liquid for, e.g., 1 to 10 minutes, so that PEG (the plating suppressor) is adsorbed on the surface of the substrate W prior to plating of the substrate W.

The pretreatment liquid (or the pure water) used in this embodiment preferably has a dissolved oxygen concentration of 2 mg/L or lower. The concentration of the oxygen dissolved in the pretreatment liquid can be adjusted by a vacuum deaerator. The pretreatment liquid having such a dissolved oxygen concentration can have a good permeability and can therefore enter the via holes 12 formed in the substrates W.

The substrate holders 160, holding the pretreated substrates W thereon, are transported to the first water-cleaning device 168a in the same manner, and the surfaces of the substrates W are cleaned with pure water held in the water-cleaning baths 184a of the first water-cleaning device 168a. This cleaning of the substrates is performed so as to remove in advance the excessive pretreatment liquid attached to the surfaces of the substrates W. This water cleaning process is performed when it is necessary.

After the water cleaning process, the two substrate holders 160, each loaded with the substrate W, are transported to positions above the plating baths 186 of the electroplating device 170 in the same manner as described above. The plating baths 186 have been filled with a predetermined amount of plating solution Q having a predetermined composition, with the plating solution Q circulating through the circulation system. The substrate holders 160 are then lowered until the substrates W, held by the substrate holders 160, are immersed in the plating solution Q in the plating baths 186. Each substrate W is disposed in the plating solution Q at a position facing the anode 220 held by the anode holder 222.

Each substrate W is immersed in the plating solution Q for a predetermined period of time, e.g., 30 to 120 seconds, without applying a voltage between the anode 220 and the copper seed layer 16 of the substrate W, so that the pretreatment liquid, attached to the surface of the substrate W including the interiors of the via holes 12, is completely replaced with the plating solution Q.

As necessary, the agitating paddle 232 is reciprocated parallel to the substrate W to agitate the plating solution Q between the regulation plate 224 and the substrate W. Agitating of the plating solution Q can promote the replacement of the pretreatment liquid, existing in the via holes 12, with the plating solution Q.

Next, electroplating is performed by applying the voltage between the anode 220 and the copper seed layer 16 to deposit a plating metal (copper) on the surface of the copper seed layer 16, thereby embedding the plating metal (copper) into the via holes 12.

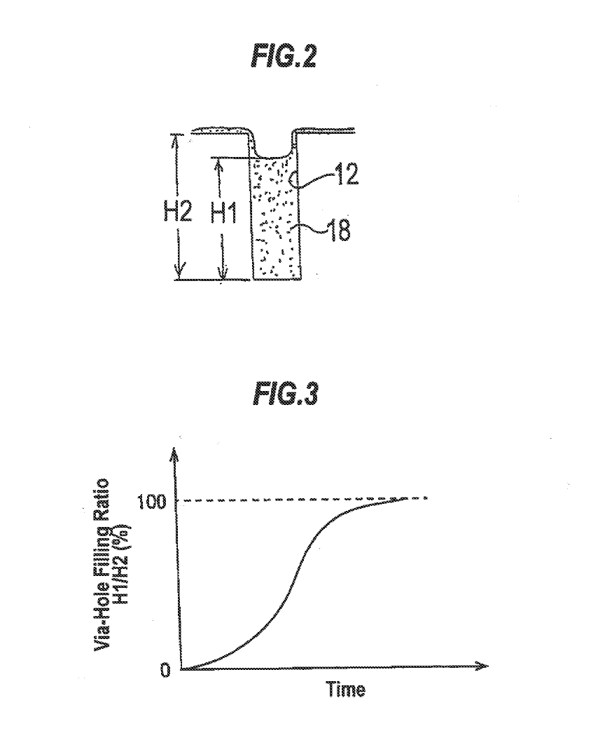

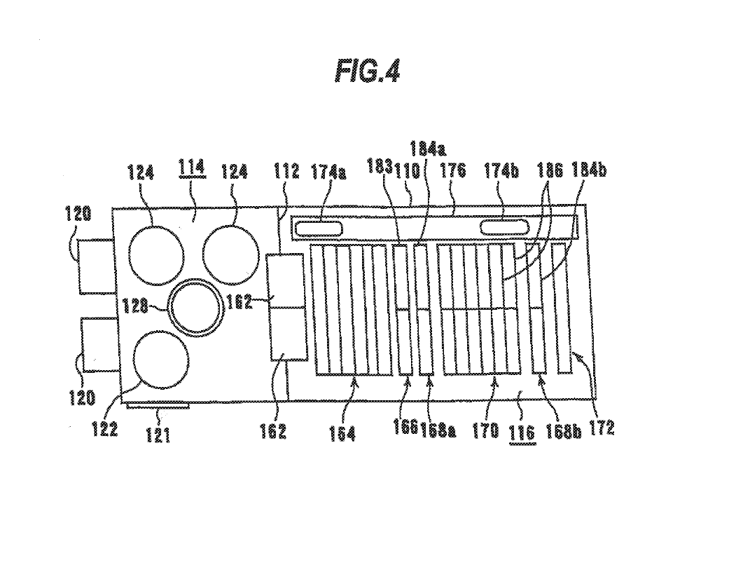

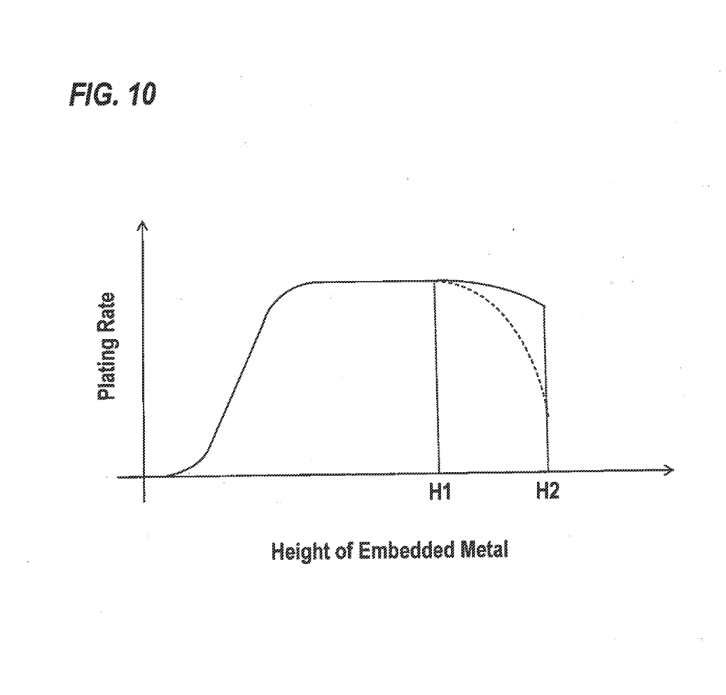

The concentration of the plating suppressor comprising PEG in the plating solution Q is, for example, about 7.5 ml/L. As described above, if plating is carried out using a plating solution containing the plating suppressor comprising PEG e.g., in a concentration of about 15 ml/L, a rapid decrease in the plating rate will occur when the height H1 of the plating metal 18 embedded in the via holes 12 reaches e.g., about 60 to 90% of the overall height H2 of the via holes 12 (H1/H2≈0.6-0.9), as shown in FIGS. 2 and 3. This is illustrated by an imaginary line in FIG. 10 showing a relationship between the plating rate and the height of the embedded metal.

It is possible to prevent such a rapid decrease in the plating rate by using a plating solution containing the plating suppressor comprising PEG in a concentration as low as about 7.5 ml/L as in this embodiment. Specifically, reducing the concentration of the plating suppressor from about 15 ml/L to about 7.5 ml/L can lead to a decrease in the amount of the plating suppressor adsorbed on the surface of the plating metal embedded in the via holes 12. This can prevent a rapid decrease in the plating rate from occurring when the height H1 of the plating metal 18 embedded in the via holes 12 reaches e.g., about 60 to 90% of the overall height H2 of the via holes 12 (H1/H2≈0.6-0.9) during the via-hole filing plating, as shown by a solid line in FIG. 10.

However, if plating is carried out merely by using the plating solution containing the PEG suppressor in a concentration as low as about 7.5 ml/L, the deposition of the plating metal 18 will be promoted also around the openings of the via holes 12. The openings of the via holes 12 will therefore be closed by the plating metal 18 before filling of the metal 18 into the via holes 12 is completed, resulting in the formation of voids in the metal 18 embedded in the via holes 12.

According to this embodiment, PEG, serving as the plating suppressor, is adsorbed onto the surface of the substrate W in advance through the pretreatment process that is performed by immersing the substrate W in the pretreatment liquid containing PEG as the plating suppressor. The PEG (plating suppressor) that has been adsorbed in advance on the surface of the substrate W, together with PEG (plating suppressor) contained in the plating solution, can prevent the formation of voids in the plating metal embedded in the via holes.

After the substrates W are immersed in the plating solution Q and until the electroplating process is terminated, the agitating paddles 232 are moved back and forth parallel to the substrates W to agitate the plating solution Q existing between the regulation plates 224 and the substrates W. The agitation intensity of the plating solution may be lowered when the aspect ratio of the via holes 12 is reduced to such an extent that the plating solution Q can easily reach the surface of the plating metal 18 in the via holes 12. If the plating solution Q is still strongly agitated by the agitating paddles 232 at this time, the growth of the plating metal may be slowed down, requiring a more time until the via holes 12 are fully embedded. To avoid this, it is desirable that the plating solution Q be agitated less intensively when the plating process has progressed to a certain extent.

After the electroplating process is terminated, the application of the voltage between the anode 220 and the copper seed layer 16 of each substrate W is stopped. Thereafter, the two substrate holders 160, each loaded with the substrate W, are held again by the second transfer robot 174b and raised from the plating baths 186.

The two substrate holders 160 are then transported to the second water-cleaning device 168b in the same manner as described above, where the surfaces of the substrates W are cleaned by immersing the substrates W in pure water held in the water-cleaning baths 184b. Thereafter, the substrate holders 160, each loaded with the substrate W, are transported to the blowing device 172 in the same manner as described above, where the plating solution and liquid droplets are removed from the substrate holders 160 by blowing air or an inert gas onto the substrate holders 160. Thereafter, the substrate holders 160, each loaded with the substrate W, are returned to the storage unit 164 and are each suspended and held at a predetermined position in the storage unit 164 in the same manner as described above.

The second transfer robot 174b sequentially repeats the above operations to sequentially return substrate holders 160, each loaded with an electroplated substrate, to predetermined positions in the storage unit 164 and suspend the substrate holders 160 in the storage unit 164. On the other hand, the two substrate holders 160 loaded with the electroplated substrates, which have been returned to the storage unit 164, are simultaneously gripped by the second transfer robot 174a, and are placed on the substrate loading and unloading stages 162 in the same manner as described above.

The first transfer robot 128, disposed in the clean space 114, takes the substrate out of the substrate holder 160 placed on one of the substrate loading and unloading stages 162 and transports the substrate to one of the cleaning and drying devices 124. In the cleaning and drying device 124, the substrate, which is held in a horizontal position with its front surface facing upwardly, is cleaned with pure water or the like and then spin-dried by rotating it at a high speed. Thereafter, the substrate is returned by the first transfer robot 128 to the substrate cassette mounted on the loading and unloading port 120, thereby completing a series of the electroplating operations.

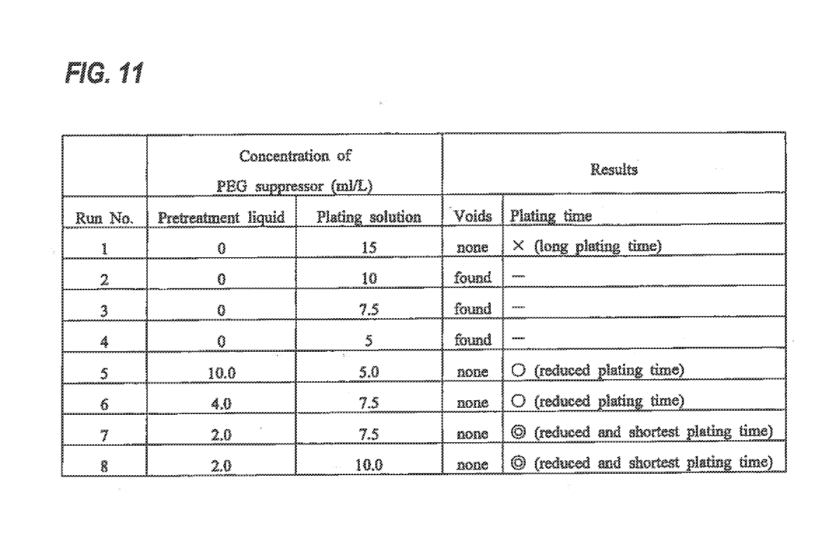

The inventors have conducted experiments on a via-hole filing electroplating process using pretreatment liquids having various concentrations of a suppressor (additive) containing PEG, and plating solutions having various concentrations of the suppressor containing PEG. The results of the experiment are summarized in a table shown in FIG. 11. Voids were formed in the metal embedded in the via holes when a plating process was carried out using a pretreatment liquid containing no plating suppressor therein and using a plating solution containing the plating suppressor in a concentration of 5.0 ml/L, 7.5 ml/L and 10.0 ml/L. In contrast, no voids were formed when a plating process was carried out using a pretreatment liquid containing the plating suppressor therein under a condition that a ratio (or percentage) of the concentration of the plating suppressor in the pretreatment liquid to the concentration of the plating suppressor in the plating solution was in the range of 20 to 200%. It was also found that the plating time can be reduced, as compared to a conventional plating method using a plating solution containing the plating suppressor in a concentration of 15.0 ml/L. In particular, the plating time was found to be shortest and the best result can be obtained when the ratio (or the percentage) of the concentration of the plating suppressor in the pretreatment liquid to the concentration of the plating suppressor in the plating solution is in a range of 20 to 30%.

According to the electroplating method of this embodiment, the substrate is immersed in the pretreatment liquid containing the plating suppressor (containing PEG) in a concentration of, e.g., about 2.0 ml/L in the pretreatment process performed in advance of plating of the substrate, so that the plating suppressor is adsorbed onto the surface of the substrate in advance. This pretreatment can prevent the formation of voids in the plating metal embedded in the via holes in the later plating process even if the plating process is performed using the plating solution containing the plating suppressor in a concentration as low as about 7.5 ml/L. Moreover, the use of such plating solution having a low concentration of the plating suppressor, such as about 7.5 ml/L, can reduce the amount of the plating suppressor adsorbed on the surface of the plating metal embedded in the via holes, thereby preventing a rapid decrease in the plating rate during filling of the plating metal into the via holes.

Another embodiment will now be described. In this embodiment the surface of the substrate W as shown in FIG. 1A through FIG. 1C, having the barrier layer 14 and the copper seed layer 16 formed on the entire surface including the interior surfaces of via holes 12, is subjected to a sequence of plating steps comprising copper electroplating of the substrate surface using a copper sulfate plating solution to fill the via holes 12 with copper (plating metal) with use of the plating facility shown in FIG. 4.

The power source 250, which is used in this embodiment, is configured to be capable of reversing the polarity. The power source 250 is coupled to the controller 252 and controlled based on a signal from the controller 252.

First, the substrate W is placed, with its front surface (surface to be plated) facing upwardly, in the substrate cassette, and the substrate cassette is mounted to the loading and unloading port 120. One of the substrates W is taken out of the substrate cassette by the first transfer robot 128 and placed on the aligner 122, which aligns an orientation flat or a notch of the substrate W with a predetermined direction. Two substrate holders 160, which have been stored in a vertical position in the storage unit 164, are taken out by the second transfer robot 174a, rotated through 90° so that the substrate holders 160 are brought into a horizontal position, and then placed in parallel on the substrate loading and unloading stages 162.

The substrates W aligned the orientation flat or the notch thereof with a predetermined direction are transported and loaded into the substrate holders 160 placed on the substrate loading and unloading stages 162 in a state such that the peripheral portions of the substrates are sealed. The two substrate holders 160, which have been loaded with the substrates W, are simultaneously gripped, lifted, and then transported to the storage unit 164 by the second transfer robot 174a. The substrate holders 160 are rotated through 90° into a vertical position and lowered so that the two substrate holders 160 are held (temporarily stored) in the storage unit 164 in a suspended manner. These operations are carried out repeatedly in a sequential manner, so that substrates are sequentially loaded into the substrate holders 160, which have been stored in the storage unit 164, and the substrate holders 160, loaded with the substrates W, are sequentially held (temporarily placed) in the storage unit 164 at predetermined positions in a suspended manner.

The two substrate holders 160, which have been loaded with the substrates and temporarily stored in the storage unit 164, are simultaneously gripped, lifted, and then transported to the pretreatment device 166 by the second transfer robot 174b. In the pretreatment device 166, the substrates W held by the substrate holders 160 are immersed in the pretreatment liquid held in the pretreatment baths 183, so that the pretreatment (or the pre-wetting treatment) is carried out on the surface of the substrate W. The pretreatment liquid used in this embodiment preferably has a dissolved oxygen concentration of 2 mg/L or lower. The concentration of the oxygen dissolved in the pretreatment liquid can be adjusted by a vacuum deaerator. The pretreatment process performed on the surface of the substrate W with the use of such pretreatment liquid can improve a hydrophilicity of the surface of the substrate. Moreover, the pretreatment liquid having such a dissolved oxygen concentration can have a good permeability and can therefore enter the via holes 12 formed in the substrates W.

The substrate holders 160, holding the pretreated substrates W thereon, are transported to the first water-cleaning device 168a in the same manner, and the surfaces of the substrates W are cleaned with the pure water held in the water-cleaning baths 184a of the first water-cleaning device 168a.

After the water cleaning process, the two substrate holders 160, each loaded with the substrate W, are transported to positions above the plating baths 186 of the electroplating device 170 in the same manner as described above. The plating baths 186 have been filled with a predetermined amount of plating solution Q having a predetermined composition, with the plating solution Q circulating through the circulation system. The substrate holders 160 are then lowered until the substrates W, held by the substrate holders 160, are immersed in the plating solution Q in the plating baths 186. Each substrate W is disposed in the plating solution Q at a position facing the anode 220 held by the anode holder 222.

The plating solution Q used in this embodiment is an acidic copper sulfate plating solution comprising sulfuric acid, copper sulfate, a halide ion and the following organic additives: the plating accelerator comprising SPS (bis(3-sulfopropyl)disulfide); the plating suppressor comprising PEG (polyethylene glycol); and the leveler comprising PEI (polyethylene imine). The plating solution Q contains the plating suppressor comprising PEG in an amount of about 15 ml/L, for example. A chloride ion is preferably used as the halide ion.

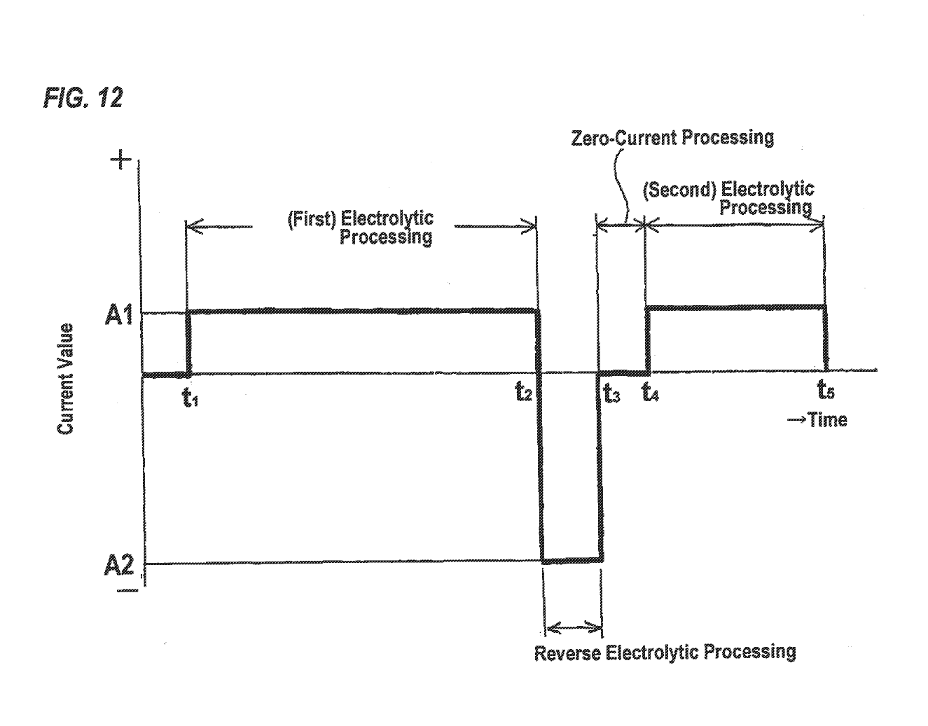

FIG. 12 shows a relationship between time and the value of electric current flowing between the anode 220 and the copper seed layer 16 (see FIGS. 1A through 1C) of the substrate W during plating in the plating apparatus 170.

As shown in FIG. 12, the substrate W is first immersed in the plating solution Q for a predetermined time period (˜t₁) without passing an electric current between the anode 220 and the copper seed layer 16 of the substrate W, so that the pretreatment liquid, attached to the surface of the substrate W including the interiors of the via holes 12, is replaced with the plating solution Q. This immersion time t₁ is, for example, 30 to 120 seconds.

Next, electrolytic processing (first electrolytic processing) of the substrate is carried out for a predetermined time period (t₁-t₂) by applying a voltage between the anode 220 and the copper seed layer 16 of the substrate W so that electric current at a predetermined value A1, e.g., 0.02 ASD (A/dm²) (A1=0.02 ASD) flows between the anode 220 and the copper seed layer 16. The first electrolytic processing time (t₁-t₂) is, for example, about 60 minutes in the case where the via holes have a diameter of 10 μm and a depth of 100 μm.

By performing the first electrolytic processing in this manner, the plating metal 18 is embedded into the via holes 12 until the height H1 of the metal 18 embedded in the via holes 12 reaches e.g., about 60 to 90% of the overall height H2 of the via holes 12 (H1/H2≈0.6-0.9), as shown in FIG. 2.

An end point of the first electrolytic processing varies depending on the aspect ratio of the via holes 12. For example, the end point may be a point when the height H1 of the plating metal 18 embedded in the via holes 12 reaches about 60 to 70% of the overall height H2 of the via holes 12 (H1/H2≈0.6-0.7), or may be a point when the height H1 reaches about 70 to 90% of the overall height H2 of the via holes 12 (H1/H2≈0.7-0.9).

The end point of the first electrolytic processing can be determined by, for example, a first electrolytic processing time or an accumulated current value.

Next, reverse electrolytic processing of the substrate is carried out for a predetermined time period (t₂-t₃) by regulating the voltage between the anode 220 and the copper seed layer 16 of the substrate W so that the electric current at a predetermined value A2, e.g., −0.5 ASD (A/dm²) (A2=−0.5 ASD) flows between the anode 220 and the copper seed layer 16. The reverse electrolytic processing is a process of passing the electric current in a direction as to dissolve the metal, i.e., a direction opposite to a direction of the electric current when plating is performed. The reverse electrolytic processing time (t₂-t₃) is, for example, 1 minute.

This reverse electrolytic processing can etch away (i.e., remove) the surface of the plating metal embedded in the via holes on which a large amount of the plating suppressor has been adsorbed, and can therefore prevent a rapid decrease in the plating rate.

After the reverse electrolytic processing is terminated, the voltage between the anode 220 and the copper seed layer 16 of the substrate W is regulated so that zero-current processing is carried out for a predetermined time period (t₃-t₄) without passing the electric current between the anode 220 and the copper seed layer 16 of the substrate W. The zero-current processing time (t₃-t₄) is, for example, 0 to 120 seconds.

By carrying out the zero-current processing as necessary, the plating suppressor can be re-adsorbed onto the plating metal surface that has been etched and exposed by the reverse electrolytic processing.

Next, electrolytic processing (second electrolytic processing) of the substrate is carried out for a predetermined time period (t₄-t₅) by applying the voltage between the anode 220 and the copper seed layer 16 of the substrate W so that the electric current at a predetermined value A1, e.g., 0.02 ASD (A/dm²) (A1=0.02 ASD) flows between the anode 220 and the copper seed layer 16 of the substrate W. The second electrolytic processing time (t₄-t₅) is, for example, about 30 minutes in the case where the via holes have a diameter of 10 μm and a depth of 100 μm.

This second electrolytic processing can completely fill the via holes 12 with the metal 18 to complete the filling process, as shown in FIG. 1B.

In this embodiment the first electrolytic processing and the second electrolytic processing are carried out so as to pass the electric current at the predetermined value A1 between the anode 220 and the copper seed layer 16 of the substrate W. It is also possible to pass the electric current at a higher value A2 (A2>A1) between the anode 220 and the copper seed layer 16 of the substrate W at a later stage of the second electrolytic processing in order to reduce the plating time.

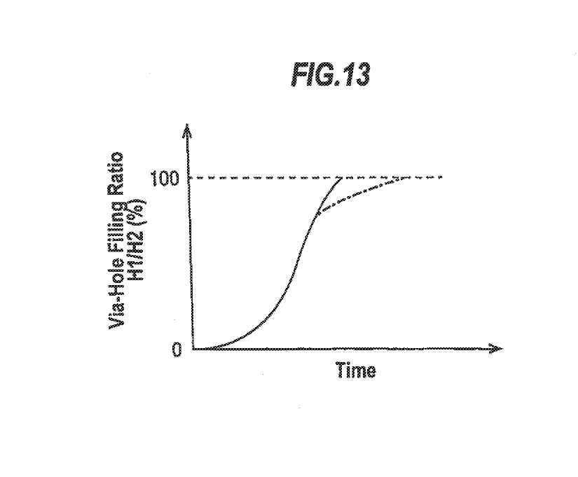

The plating solution Q for use in the plating process contains the plating suppressor comprising PEG in an amount of, e.g., about 15 ml/L. A void-free plating metal can be filled into the via holes by carrying out plating using the plating solution Q containing such a high concentration of PEG. However, if plating is carried out using the plating solution Q containing such a high concentration of PEG without carrying out the reverse electrolytic processing, a rapid decrease in the plating rate will occur when the height H1 of the plating metal 18 embedded in the via holes 12 reaches e.g., about 70 to 90% of the overall height H2 of the via holes 12 (H1/H2≈0.7-0.9), as shown in FIGS. 2 and 3. This is illustrated by the imaginary line in FIG. 13 which shows a relationship between the plating rate and the height of the embedded metal.

In this embodiment the reverse electrolytic processing is carried out when the height H1 of the plating metal 18 embedded in the via holes 12 reaches e.g., about 60 to 90% of the overall height H2 of the via holes 12 (H1/H2≈0.6-0.9), thereby etching away or remove the surface of the plating metal embedded in the via holes on which a large amount of the plating suppressor has been adsorbed. This makes it possible to prevent a rapid decrease in the plating rate in the later plating process, as shown by the solid line in FIG. 13.

During a period of time from the start of immersion of the substrate W in the plating solution Q to the end of electroplating, the agitating paddle 232 may be reciprocated parallel to the substrate W to agitate the plating solution Q between the regulation plate 224 and the substrate W as necessary. The aspect ratio of the via holes decreases with the progress of the via-hole filing plating. If strong agitation of the plating solution Q is continued even after the aspect ratio of the via holes is lowered until the plating solution can easily reach the surface of the plating metal in the via holes, the growth of plating may be slowed down, resulting in an unfavorably long time to complete the via-hole filing plating. In such a case, therefore, it is preferred to reduce the intensity of agitating the plating solution Q when the plating has progressed to some extent.

In this embodiment the agitating paddle 232 is reciprocated at a reciprocation rate of about 250 times per minute until the end of the reverse electrolytic processing, and the reciprocation rate of the agitating paddle 232 is lowered to about 20 times per minute after the reverse electrolytic processing is terminated.

After the electroplating process is terminated, the application of the voltage between the anode 220 and the copper seed layer 16 of each substrate W is stopped. Thereafter, the two substrate holders 160, each loaded with the substrate W, are held again by the second transfer robot 174b and raised from the plating baths 186.

The two substrate holders 160 are then transported to the second water-cleaning device 168b in the same manner as described above, where the surfaces of the substrates W are cleaned by immersing the substrates W in pure water held in the water-cleaning baths 184b. Thereafter, the substrate holders 160, each loaded with the substrate W, are transported to the blowing device 172 in the same manner as described above, where the plating solution and liquid droplets are removed from the substrate holders 160 by blowing air or an inert gas onto the substrate holders 160. Thereafter, the substrate holders 160, each loaded with the substrate W, are returned to the storage unit 164 and are each suspended and held at a predetermined position in the storage unit 164 in the same manner as described above.

The second transfer robot 174b sequentially repeats the above operations to sequentially return substrate holders 160, each loaded with an electroplated substrate, to predetermined positions in the storage unit 164 and suspend the substrate holders 160 in the storage unit 164. On the other hand, the two substrate holders 160 loaded with the electroplated substrates, which have been returned to the storage unit 164, are simultaneously gripped by the second transfer robot 174a, and are placed on the substrate loading and unloading stages 162 in the same manner as described above.

The first transfer robot 128, disposed in the clean space 114, takes the substrate out of the substrate holder 160 placed on one of the substrate loading and unloading stages 162 and transports the substrate to one of the cleaning and drying devices 124. In the cleaning and drying device 124, the substrate, which is held in a horizontal position with its front surface facing upwardly, is cleaned with pure water or the like and then spin-dried by rotating it at a high speed. Thereafter, the substrate is returned by the first transfer robot 128 to the substrate cassette mounted on the loading and unloading port 120, thereby completing a series of the electroplating operations.

According to the above-described embodiment of the electroplating method, the reverse electrolytic processing is carried out when the height of the plating metal embedded in the via holes reaches about 60 to 90% of the overall height of the via holes, thereby etching away the surface of the plating metal embedded in the via holes. This can prevent a rapid decrease in the plating rate even if plating of the substrate is carried out using the plating solution containing the plating suppressor comprising PEG in a relatively large amount, such as 15 ml/L, in order to fill a void-free plating metal into via holes.

While the present invention has been described with reference to preferred embodiments, it is understood that the present invention is not limited to the embodiments described above, but is capable of various changes and modifications within the scope of the inventive concept as expressed herein.

What is claimed is:

1. An electroplating method, comprising:
preparing a substrate having via holes in a surface thereof;
performing a pretreatment of the substrate surface by immersing the substrate in a pretreatment liquid containing a plating suppressor to adsorb the plating suppressor onto the substrate surface;
immersing the pretreated substrate in a plating solution containing a plating suppressor and a plating accelerator to replace the pretreatment liquid, attached to the substrate surface including interior surfaces of the via holes, with the plating solution; and then
electroplating the substrate surface to fill the via holes with metal.

2. The electroplating method according to claim 1, wherein a ratio of a concentration of the plating suppressor in the pretreatment liquid to a concentration of the plating suppressor in the plating solution is in a range of 20 to 200%.

3. The electroplating method according to claim 2, wherein the ratio is in a range of 20 to 30%.

4. The electroplating method according to claim 1, wherein the plating suppressor comprises polyethylene glycol.

5. The electroplating method according to claim 1, wherein the pretreatment liquid further contains a metal ion and a halide ion.

6. The electroplating method according to claim 1, wherein a concentration of oxygen dissolved in the pretreatment liquid is not more than 2 mg/L.

7. The electroplating method according to claim 1, wherein immersing the pretreated substrate in the plating solution comprises immersing the pretreated substrate in a plating solution containing a plating suppressor and a plating accelerator to replace the pretreatment liquid, attached to the substrate surface including interior surfaces of the via holes, with the plating solution while agitating the plating solution.

8. The electroplating method according to claim 1, further comprising:
before immersing the pretreated substrate in the plating solution, cleaning the pretreated substrate with water.

9. An electroplating method, comprising:
preparing a substrate having via holes in a surface thereof;
performing electrolytic processing of the substrate surface by applying a voltage between an anode and the substrate immersed in a plating solution to deposit metal on the substrate, thereby embedding the metal in the via holes;
performing reverse electrolytic processing of the substrate surface by passing an electric current between the anode and the substrate in a direction opposite to a direction of the electric current in the electrolytic processing, the reverse electrolytic processing being started when a height of the metal embedded in the via holes reaches about 60 to 90% of an overall height of the via holes; and then
performing the electrolytic processing again to further embed the metal in the via holes.

10. The electroplating method according to claim 9, further comprising:
after performing the reverse electrolytic processing and before performing the electrolytic processing again, performing zero-current processing of the substrate surface without passing the electric current between the anode and the substrate.

11. The electroplating method according to claim 9, wherein the plating solution contains a plating suppressor.

12. The electroplating method according to claim 9, wherein the electrolytic processing is performed while agitating the plating solution.
